(19) United States
(12) Patent Application Publication
(10) Pub. No.: US 2022/0020575 A1
(43) Pub. Date: Jan. 20, 2022

(54) APPARATUS FOR TREATING SUBSTRATE, METHOD FOR MEASURING HEIGHT DIFFERENCE BETWEEN LIFT PINS, AND COMPUTER READABLE RECORDING MEDIUM HAVING PROCESSING PROGRAM STORED THEREIN

(71) Applicant: SEMES CO., LTD., Cheonan-si (KR)

(72) Inventors: Ming Sung Kwon, Cheonan-si (KR); Yoonghee Lee, Cheonan-si (KR)

(73) Assignee: SEMES CO., LTD., Cheonan-si (KR)

(21) Appl. No.: 17/347,431

(22) Filed: Jun. 14, 2021

(30) Foreign Application Priority Data
Jun. 15, 2020 (KR) 10-2020-0072391

(51) Int. Cl. H01J 37/32; H01L 21/687; H01L 21/68; G01B 21/04; B25J 11/00; B25J 9/16; G05B 19/4155; G08B 3/10

(52) U.S. Cl. CPC H01J 37/32715; H01L 21/68707; H01L 21/68; H01L 21/68742; H01J 37/32743; G01B 21/04; G05B 2219/40269; B25J 9/1679; G05B 19/4155; G08B 3/10; H01J 2237/20235; H01J 2237/24578; B25J 11/0095

(57) ABSTRACT

A method for measuring a height difference between lift pins includes receiving a first center position being a position of the center of a substrate with respect to a reference position that is measured before a transfer robot loads the substrate onto a support unit provided in a process chamber, the support unit including a plurality of lift pins, receiving a second center position being a position of the center of the substrate with respect to the reference position that is measured after the transfer robot picks up the substrate unloaded from the support unit, and deriving a difference in height between at least one of the plurality of lift pins and the other lift pins from a vector difference between the first center position and the second center position.

### CROSS-REFERENCE TO RELATED APPLICATIONS

A claim for priority under 35 U.S.C. § 119 is made to Korean Patent Application No. 10-2020-0072391 filed on Jun. 15, 2020, in the Korean Intellectual Property Office, the entire contents of which are hereby incorporated by reference.

### BACKGROUND

Embodiments of the inventive concept described herein relate to an apparatus for treating a substrate, a method for measuring a height difference between lift pins, and a computer readable recording medium having a processing program stored therein for executing the method.

Heights of lift pins are set to a target height from a top side of a wafer support unit (e.g., an electrostatic chuck (ECS)) by using a jig after assembly of the lift pins. A method for additionally measuring a height difference between the lift pins after the heights of the lift pins are set is not proposed up to now.

The heights of the lift pins are set by using the jig. Therefore, even though there is an error in the jig itself or the height setting step, there is no way to identify, after assembly of a process chamber (PM), occurrence or non-occurrence of a height difference between the lift pins.

### SUMMARY

Embodiments of the inventive concept provide a substrate treating apparatus for identifying occurrence or non-occurrence of a height difference between lift pins even after a process chamber (PM) is completely assembled, a lift pin height difference measurement method using the substrate treating apparatus, and a computer readable recording medium having a processing program stored therein for executing the method.

Embodiments of the inventive concept provide a substrate treating apparatus for identifying occurrence or non-occurrence of a height difference between lift pins in a simple manner by using center position coordinate information of a wafer (e.g., data collected through an auto wafer centering (AWC) function), a lift pin height difference measurement method using the substrate treating apparatus, and a computer readable recording medium having a processing program stored therein for executing the method.

Embodiments of the inventive concept provide a substrate treating apparatus for evaluating assembly of lift pins in a simple manner and identifying a lift pin having a problem in height setting, a lift pin height difference measurement method using the substrate treating apparatus, and a computer readable recording medium having a processing program stored therein for executing the method.

Embodiments of the inventive concept provide a substrate treating apparatus for identifying, after assembly of a process chamber, occurrence or non-occurrence of human and environmental errors that are likely to occur between assembly of lift pins and the assembly of the process chamber, a lift pin height difference measurement method using the substrate treating apparatus, and a computer readable recording medium having a processing program stored therein for executing the method.

Embodiments of the inventive concept provide a substrate treating apparatus for identifying, during operation of the apparatus, occurrence or non-occurrence of a height difference between lift pins and reducing a chamber release frequency by determining a failure in the lift pins, a lift pin height difference measurement method using the substrate treating apparatus, and a computer readable recording medium having a processing program stored therein for executing the method.

The technical problems to be solved by the inventive concept are not limited to the aforementioned problems, and any other technical problems not mentioned herein will be clearly understood from the following description by those skilled in the art to which the inventive concept pertains.

According to an embodiment, an apparatus for treating a substrate includes a chamber that provides a treatment space in which the substrate is treated, a support unit that is provided in the treatment space and that supports the substrate, the support unit including a plurality of lift pins that move upward or downward to locate the substrate, a transfer robot that loads the substrate into the treatment space or unloads the substrate from the treatment space, a position measurement sensor that measures a first center position being a position of the center of the substrate with respect to a reference position that is measured before the transfer robot loads the substrate onto the support unit and a second center position being a position of the center of the substrate with respect to the reference position that is measured after the transfer robot picks up the substrate unloaded from the support unit, and a processor that derives a difference in height between at least one of the plurality of lift pins and the other lift pins from a vector difference between the first center position and the second center position.

In an embodiment, the position measurement sensor may be an auto wafer centering (AWC) sensor that is installed on the top or bottom of an opening of the chamber and that measures a position of the substrate passing through the opening of the chamber.

In an embodiment, each of the first center position and the second center position may include an x-coordinate and a y-coordinate.

In an embodiment, the plurality of lift pins may be coupled to a support plate, and the support plate may be connected to an actuator that provides a driving force to raise and lower the support plate in an up/down direction.

In an embodiment, the apparatus may perform an operation of loading the substrate onto the support unit and unloading the substrate from the support unit a plurality of times, may measure the first center position a plurality of times in response to loading the substrate onto the support unit the plurality of times, may measure the second center position a plurality of times in response to unloading the substrate from the support unit the plurality of times, and may derive a difference in height between at least one of the plurality of lift pins and the other lift pins from a vector difference between an average value of the first center positions measured the plurality of times and an average value of the second center positions measured the plurality of times.

In an embodiment, before the second center position is measured after the first center position is measured, the apparatus may raise and lower the plurality of lift pins a plurality of times, with the substrate loaded onto the support unit.

In an embodiment, the plurality of lift pins may include three lift pins circumferentially spaced apart from each other at an angle of 120 degrees with respect to the center of the support unit.

In an embodiment, the substrate may slide due to a difference in height between at least one of the plurality of lift pins and the other lift pins, a sliding direction of the substrate may be opposite to a direction in which a lift pin in a relatively high position among the plurality of lift pins is located, and the vector difference between the first center position and the second center position may correspond to the sliding direction of the substrate and may be used to derive the lift pin in the relatively high position among the plurality of lift pins.

In an embodiment, when a difference in height between at least one of the plurality of lift pins and the other lift pins is derived, an alarm may be provided outside the apparatus.

According to an embodiment, a method for measuring a height difference between lift pins includes receiving a first center position being a position of the center of a substrate with respect to a reference position that is measured before a transfer robot loads the substrate onto a support unit provided in a process chamber, the support unit including a plurality of lift pins, receiving a second center position being a position of the center of the substrate with respect to the reference position that is measured after the transfer robot picks up the substrate unloaded from the support unit, and deriving a difference in height between at least one of the plurality of lift pins and the other lift pins from a vector difference between the first center position and the second center position.

In an embodiment, the first center position and the second position may be obtained by an auto wafer centering (AWC) sensor that measures a position of the substrate passing through an opening of the process chamber.

In an embodiment, the first center position may be defined as an x-y coordinate (x_{place}, y_{place}), the second center position may be defined as an x-y coordinate (x_{pick}, y_{pick}), and the vector difference between the first center position and the second center position may be defined by (x_{pick}−x_{place}, y_{pick}−y_{place}).

In an embodiment, the plurality of lift pins may be simultaneously raised and lowered by one actuator.

In an embodiment, an operation of loading the substrate onto the support unit and unloading the substrate from the support unit may be performed a plurality of times. The first center position may be measured a plurality of times in response to loading the substrate onto the support unit the plurality of times, and the second center position may be measured a plurality of times in response to unloading the substrate from the support unit the plurality of times. A difference in height between at least one of the plurality of lift pins and the other lift pins may be derived from a vector difference between an average value of the first center positions measured the plurality of times and an average value of the second center positions measured the plurality of times.

In an embodiment, an operation of loading the substrate onto the support unit and unloading the substrate from the support unit may be performed a plurality of times. The first center position may be measured a plurality of times in response to loading the substrate onto the support unit the plurality of times, and the second center position may be measured a plurality of times in response to unloading the substrate from the support unit the plurality of times. Values included in a predetermined range among the first center positions measured the plurality of times and the second center positions measured the plurality of times may be selected to be effective data. A difference in height between at least one of the plurality of lift pins and the other lift pins may be derived from a vector difference between an average value of the first center positions included in the effective data and an average value of the second center positions included in the effective data.

In an embodiment, before the second center position is measured after the first center position is measured, the plurality of lift pins may be raised and lowered a plurality of times, with the substrate loaded onto the support unit.

In an embodiment, the plurality of lift pins may include three lift pins circumferentially spaced apart from each other at an angle of 120 degrees with respect to the center of the support unit. Due to a difference in height between at least one of the three lift pins and the other lift pins, the substrate may slide, and a difference between the first center position and the second center position may occur. Among components of the vector difference between the first center position and the second center position, a vector value caused by a lift pin in the lowest position among the three lift pins may be defined as 0.

In an embodiment, the substrate may slide due to a difference in height between at least one of the plurality of lift pins and the other lift pins. A sliding direction of the substrate may be opposite to a direction in which a lift pin in a relatively high position among the plurality of lift pins is located. The vector difference between the first center position and the second center position may correspond to the sliding direction of the substrate and may be used to derive the lift pin in the relatively high position among the plurality of lift pins.

In an embodiment, when a difference in height between at least one of the plurality of lift pins and the other lift pins is derived, an alarm may be provided outside a substrate treating apparatus.

According to an embodiment, provided is a computer readable recording medium having a processing program stored therein for executing the method for measuring the height difference between the lift pins.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a schematic plan view illustrating wafer treating equipment according to an embodiment of the inventive concept;

FIG. 2 is a schematic view illustrating a relationship between a process chamber and a transfer robot in the wafer treating equipment according to an embodiment of the inventive concept;

FIG. 3 is a schematic sectional view of a process chamber of FIG. 1 according to an embodiment;

FIG. 4 is a perspective view of a lift pin assembly of FIG. 3;

FIGS. 5 and 6 are views sequentially illustrating a process of loading a wafer onto a support unit;

FIG. 7 is a sectional view illustrating one example of a height difference between lift pins in the lift pin assembly of FIG. 3;

FIG. 8 illustrates a center position P1 of a wafer and the coordinates of the center position P1 that are collected through an AWC function before the wafer is loaded onto the support unit of the process chamber;

FIG. 9 illustrates a center position P2 of the wafer and the coordinates of the center position P2 that are collected through the AWC function after the wafer is unloaded from the support unit of the process chamber;

FIG. 10 illustrates a vector difference between the coordinates of the center position P2 illustrated in FIG. 9 and the coordinates of the center position P1 illustrated in FIG. 8;

FIGS. 11, 12, and 13 are views illustrating a method for calculating a height difference between lift pins according to an embodiment of the inventive concept; and

FIGS. 14A and 14B illustrate a flowchart showing an operation algorithm of an apparatus for measurement of a height difference between lift pins according to an embodiment of the inventive concept.

### DETAILED DESCRIPTION

Hereinafter, embodiments of the inventive concept will be described in more detail with reference to the accompanying drawings. The inventive concept may, however, be embodied in different forms and should not be construed as limited to the embodiments set forth herein. Rather, these embodiments are provided so that the inventive concept will be thorough and complete, and will fully convey the scope of the inventive concept to those skilled in the art. In the drawings, the dimensions of components are exaggerated for clarity of illustration.

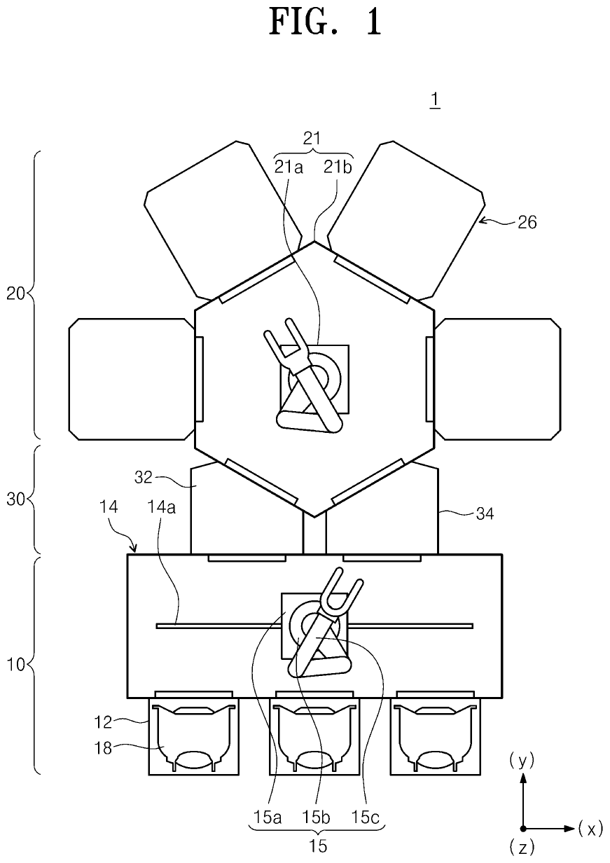

FIG. 1 is a schematic plan view illustrating wafer treating equipment according to an embodiment of the inventive concept. The wafer treating equipment 1 according to the embodiment of the inventive concept will be described below with reference to FIG. 1. The wafer treating equipment 1 includes an index module 10, a loading module 30, and a process module 20.

The index module 10 includes a load port 12 and a transfer frame 14. The load port 12 and the transfer frame 14 are sequentially arranged in a row. Hereinafter, a direction in which the index module 10, the loading module 30, and the process module 20 are arranged is referred to as a first direction y, a direction perpendicular to the first direction y when viewed from above is referred to as a second direction x, and a direction perpendicular to a plane including the first direction y and the second direction x is referred to as a third direction z.

A carrier 18 having a plurality of wafers W received therein is placed on the load port 12. A plurality of load ports 12 may be provided. The load ports 12 may be disposed in a row along the second direction x. FIG. 1 illustrates one example that the index module 10 includes three load ports 12. However, the number of load ports 12 may be increased or decreased depending on conditions such as process efficiency and footprint of the process module 20. A plurality of slots (not illustrated) that support edges of the wafers W are formed in the carrier 18. The plurality of slots are arranged along the third direction z, and the wafers W are located in the carrier 18 so as to be stacked one above another with a spacing gap therebetween along the third direction z. A front opening unified pod (FOUP) may be used as the carrier 18. The transfer frame 14 transfers the wafers W between the carrier 18 seated on the load port 12 and the loading module 30. An index rail 14a and an index robot 15 are provided in the transfer frame 14. The index rail 14a is disposed such that the lengthwise direction thereof is parallel to the second direction x. The index robot 15 is provided on the index rail 14a and is rectilinearly moved along the index rail 14a in the second direction x. The index robot 15 includes a base 15a, a body 15b, and an index arm 15c. The base 15a is movable along the index rail 14a. The body 15b is coupled to the base 15a. The body 15b is movable on the base 15a along the third direction z. Furthermore, the body 15b is rotatable on the base 15a. The index arm 15c is coupled to the body 15b and is movable forward and backward relative to the body 15b. A plurality of index arms 15c may be provided. The index arms 15c may be individually driven. The index arms 15c are stacked one above another with a spacing gap therebetween along the third direction z. Some of the index arms 15c may be used to transfer the wafers W from the process module 20 to the carrier 18, and the other index arms 15c may be used to transfer the wafers W from the carrier 18 to the process module 20. Accordingly, particles generated from the wafers W to be treated may be prevented from adhering to the treated wafers W in a process in which the index robot 15 transfers the wafers W between the carrier 18 and the process module 20. The loading module 30 is disposed between the transfer frame 14 and a transfer chamber 21b. The loading module 30 provides a space in which the wafers W stay before transferred between the transfer chamber 21b and the transfer frame 14. The loading module 30 includes a load-lock chamber 32 and an unload-lock chamber 34. The load-lock chamber 32 and the unload-lock chamber 34 are provided such that the insides thereof are able to be switched between a vacuum atmosphere and an atmospheric atmosphere. The load-lock chamber 32 provides a space in which the wafers W to be transferred from the index module 10 to the process module 20 temporarily stay. When the wafers W are placed in the load-lock chamber 32, an inner space of the load-lock chamber 32 is sealed from the index module 10 and the process module 20. Thereafter, the inner space of the load-lock chamber 32 is switched from the atmospheric atmosphere to the vacuum atmosphere, and the load-lock chamber 32 is open to the process module 20 in the state of being sealed from the index module 10.

The unload-lock chamber 34 provides a space in which the wafers W to be transferred from the process module 20 to the index module 10 temporarily stay. When the wafers W are placed in the unload-lock chamber 34, an inner space of the unload-lock chamber 34 is sealed from the index module 10 and the process module 20. Thereafter, the inner space of the unload-lock chamber 34 is switched from the vacuum atmosphere to the atmospheric atmosphere, and the unload-lock chamber 34 is open to the index module 10 in the state of being sealed from the process module 20.

The process module 20 includes the transfer chamber 21b and a plurality of process chambers 26.

The transfer chamber 21b transfers the wafers W between the load-lock chamber 32, the unload-lock chamber 34, and the plurality of process chambers 26. The transfer chamber 21b may have a hexagonal shape when viewed from above. Selectively, the transfer chamber 21b may have a rectangular or pentagonal shape. The load-lock chamber 32, the unload-lock chamber 34, and the plurality of process chambers 26 are located around the transfer chamber 21b. A transfer robot 21a is provided in the transfer chamber 21b. The transfer robot 21a may be located in the center of the transfer chamber 21b.

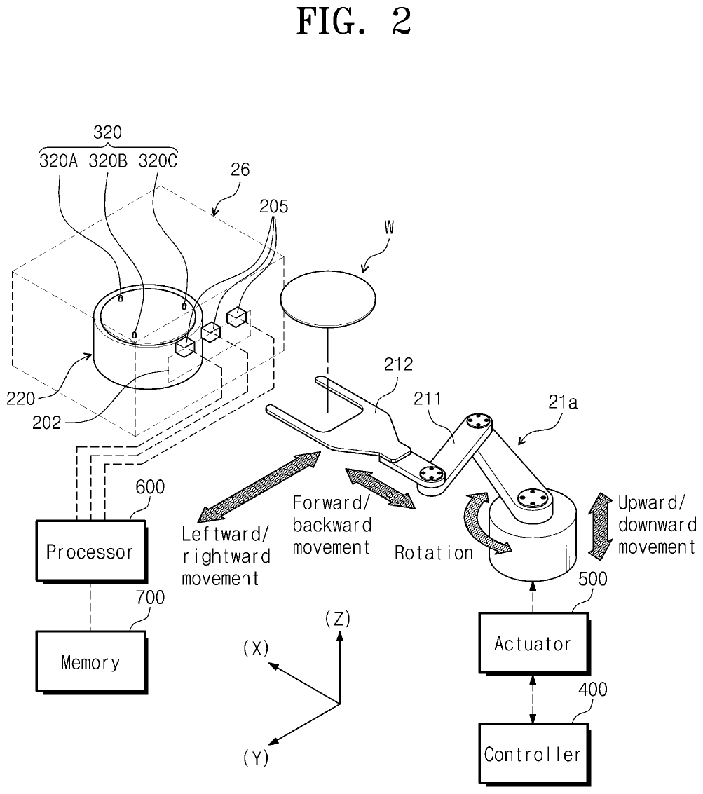

FIG. 2 is a schematic view illustrating a relationship between the process chamber 26 and the transfer robot 21a in the wafer treating equipment 1 according to an embodiment of the inventive concept. Referring to FIG. 2, the wafer treating equipment 1 (refer to FIG. 1) includes, for example, the process chamber 26 that performs an etching process using plasma, the transfer robot 21a that supplies a wafer W to the process chamber 26, a controller 400 that controls an operation of the transfer robot 21a, and an actuator 500 that moves the transfer robot 21a leftward, rightward, forward, backward, upward, and downward and rotates the transfer robot 21a under the control of the controller 400. The transfer robot 21a includes an arm 211 and an end effector 212. The transfer robot 21a transfers the wafer W onto a support unit 220 through an entrance/exit opening 202 of the process chamber 26. The wafer W may be seated on the end effector 212 in a horizontal state.

A position measurement sensor 205 may be installed in the entrance/exit opening 202 of the process chamber 26. The position measurement sensor 205 may be installed on the top or bottom of the entrance/exit opening 202, or may be installed on the top and bottom of the entrance/exit opening 202. The position measurement sensor 205 measures the position of the wafer W passing through the entrance/exit opening 202. The position measurement sensor 205 measures the position of the wafer W transferred from a transfer module 21 to the process chamber 26 or from the process chamber 26 to the transfer module 21 through the entrance/exit opening 202. Specifically, the position measurement sensor 205 measures the coordinates of the center of the wafer W passing through the entrance/exit opening 202. For example, the position measurement sensor 205 may measure the coordinates of the center of the wafer W during a time when the wafer W passes through the entrance/exit opening 202. In an embodiment, the position measurement sensor 205 may be implemented with an auto wafer centering (AWC) sensor. A plurality of AWC sensors may be installed to be symmetric with respect to a vertical center line M of the entrance/exit opening 202. Korean Patent No. 10-1408164 and Korean Patent Publication No. 10-2020-0010744 may be referred to in relation to an AWC sensor and acquisition of the coordinates of the center of a wafer using the AWC sensor.

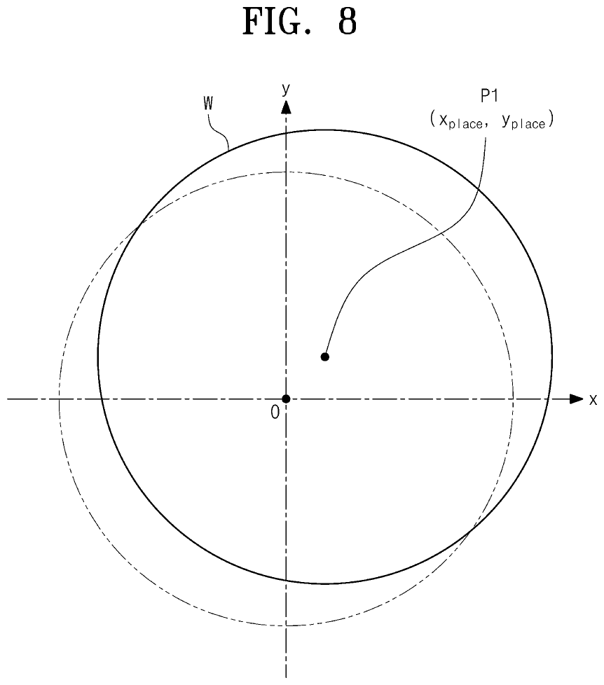

The position measurement sensor 205 may exchange data with a non-transitory computer readable medium having a program stored therein for sequentially performing a substrate treating method that will be described below with reference to FIGS. 8 to 14. The computer readable medium may include a processor 600 and a memory 700. The processor 600 may derive a height difference between at least one of a plurality of lift pins and the other lift pins from a vector difference between a first center position and a second center position that will be described below.

Depending on position information of the wafer W measured by the position measurement sensor 205, the controller 400 may control an operation of the end effector 212 such that the wafer W is located in the center of a seating part of the support unit 220 of the process chamber 26.

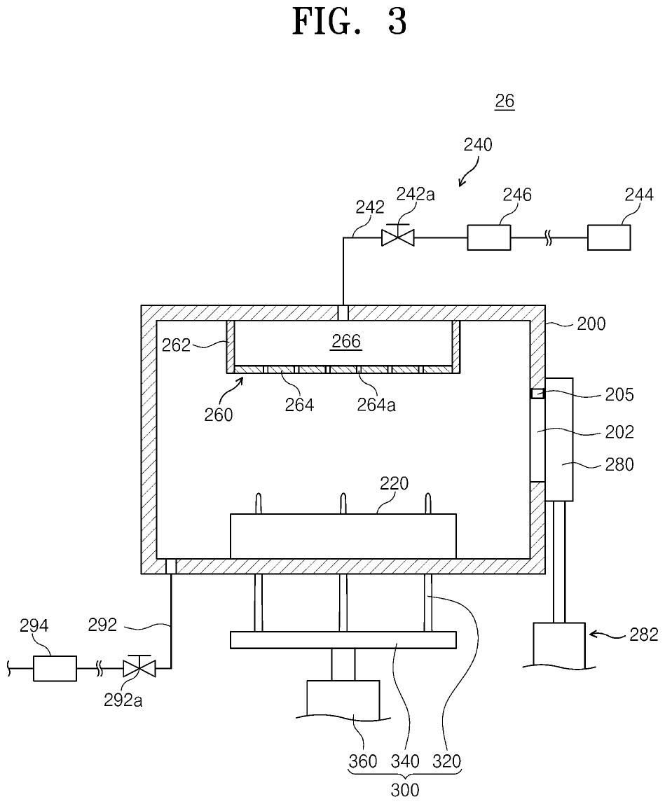

FIG. 3 is a schematic sectional view of the process chamber 26 of FIG. 1 according to an embodiment. According to an embodiment, the process chamber 26 may perform an etching process on a wafer W. Referring to FIG. 3, the process chamber 26 includes a housing 200, the support unit 220, a gas supply member 240, a showerhead 260, and a lift pin assembly 300. The housing 200 has a container shape having an inner space in which the process is performed. The housing 200 has, in a sidewall thereof, the entrance/exit opening 202 through which the wafer W enters and exits the housing 200. The opening 202 is opened and closed by a door 280. The door 280 is slid upward and downward by an actuator 282 such as a hydraulic/pneumatic cylinder. An exhaust tube 292 for discharging by-products generated during the process is connected to a lower wall of the housing 200. A pump 294 and a valve 292a are disposed in-line with the exhaust tube 292. The pump 294 maintains the pressure in the housing 200 at a process pressure while the process is performed, and the valve 292a opens and closes a passage in the exhaust tube 292.

The support unit 220 supports the wafer W while the process is performed. The support unit 220 has a substantially cylindrical shape. An upper surface of the support unit 220 has a smaller size than the wafer W. For example, the diameter of the upper surface of the support unit 220 is smaller than the diameter of the wafer W. The support unit 220 may fix the wafer W by vacuum pressure, electrostatic force, or mechanical clamping. Furthermore, the upper surface of the support unit 220 may be formed to be flat, or may have micro-protrusions making contact with the backside of the wafer W. The gas supply member 240 supplies a process gas into the housing 200. The process gas may etch a film on the wafer W. The process gas may be supplied in a plasma state. The gas supply member 240 includes a gas supply tube 242 and a plasma generator 246. The gas supply tube 242 connects a gas supply source 244 and the housing 200. A valve 242a is disposed in-line with the gas supply tube 242 to open and close a passage in the gas supply tube 242. The plasma generator 246 is disposed in-line with the gas supply tube 242 and generates plasma from the process gas. Alternatively, the plasma generator 246 may be mounted on the top of the housing 200. A compound containing fluorine may be used as the process gas.

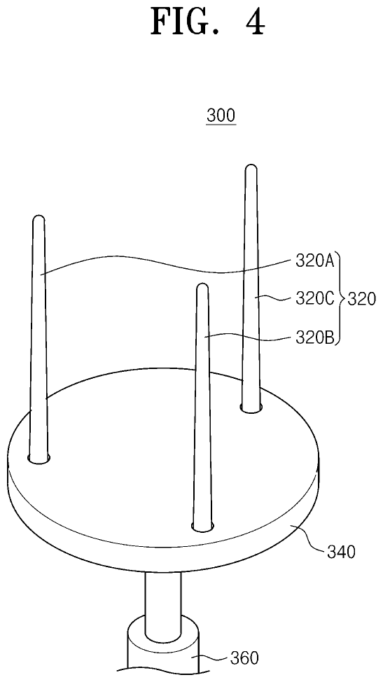

The showerhead 260 uniformly distributes the process gas introduced into the housing 200 to the wafer W. Inside the housing 200, the showerhead 260 is located in a higher position than the support unit 220 so as to face the support unit 220. The showerhead 260 has an annular sidewall 262 and a circular distribution plate 264. The sidewall 262 of the showerhead 260 is fixedly coupled to the housing 200 so as to protrude downward from an upper wall of the housing 200. The distribution plate 264 is fixedly coupled to a lower end of the sidewall 262. A plurality of dispensing holes 264a may be formed in the entire area of the distribution plate 264. The process gas is introduced into a space 266 formed by the housing 200 and the showerhead 260 and thereafter is dispensed onto the wafer W through the dispensing holes 264a. The lift pin assembly 300 loads the wafer W onto the support unit 220, or unloads the wafer W from the support unit 220. FIG. 4 is a perspective view of the lift pin assembly 300. Referring to FIGS. 3 and 4, the lift pin assembly 300 includes lift pins 320, a support plate 340, and an actuator 360. In an embodiment, three lift pins 320 including a first lift pin 320A, a second lift pin 320B, and a third lift pin 320C are provided. The lift pins 320 are fixed to the support plate 340 and are moved together with the support plate 340. The support plate 340 has a circular plate shape. Inside the housing 200, the support plate 340 is located under the support unit 220. Alternatively, the support plate 340 is located outside the housing 200. The support plate 340 is raised and lowered by the actuator 360 such as a hydraulic/pneumatic cylinder or a motor. The lift pins 320, when viewed from above, are located to correspond to vertexes of an equilateral triangle. The support unit 220 has through-holes vertically formed through the support unit 220 in an up/down direction. The lift pins 320 are inserted into the respective through-holes and are raised and lowered through the through-holes. The lift pins 320 have a long rod shape, and upper ends of the lift pins 320 have a shape that is convex upward.

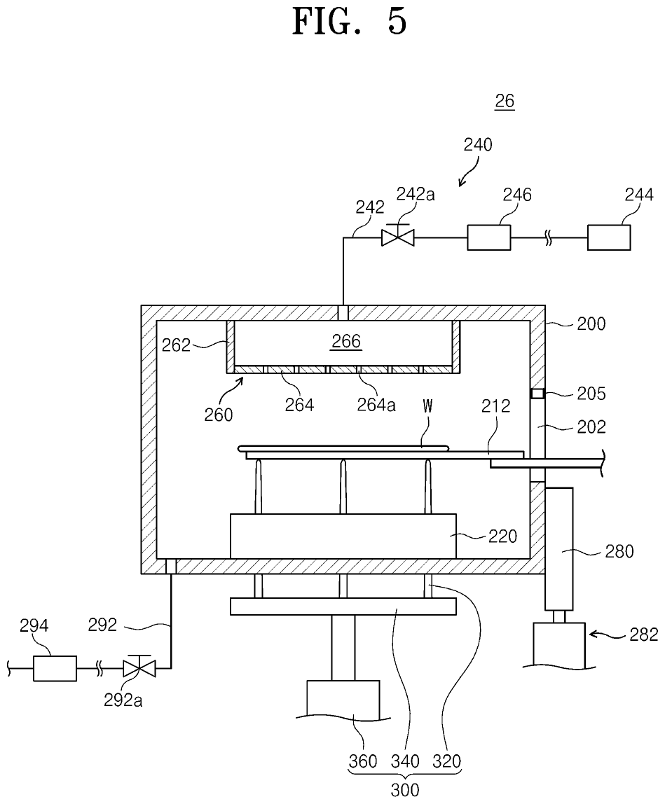

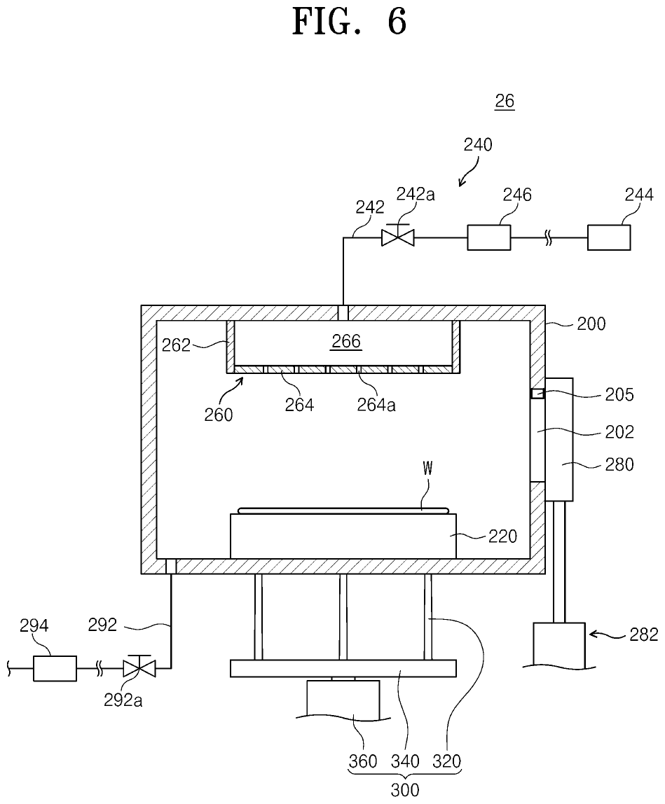

FIGS. 5 and 6 are views sequentially illustrating a process of loading a wafer onto the support unit. The process in which the wafer W is loaded onto the support unit 220 will be described below with reference to FIGS. 5 and 6. Referring to FIG. 5, for entrance of the wafer W into the housing 200, the door 280 opens the entrance/exit opening 202. The end effector 212 holding the wafer W enters the housing 200 through the open entrance/exit opening 202. At this time, the lift pins 320 are raised to receive the wafer W. When the wafer W is supported by the lift pins 320, the end effector 212 moves backward, and the entrance/exit opening 202 is closed by the door 280. Referring to FIG. 6, the lift pins 320 supporting the wafer W are lowered to place the wafer W on a support surface of the support unit 220.

A process of unloading the wafer W from the support unit 220 is performed in reverse order to that in which the wafer W is loaded onto the support unit 220.

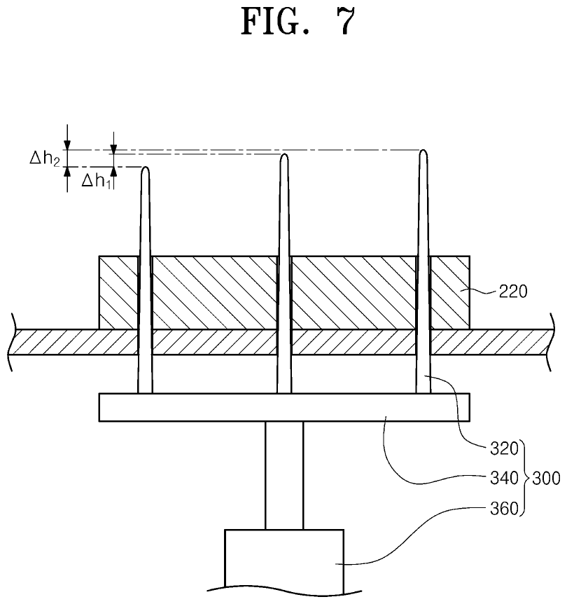

FIG. 7 is a sectional view illustrating one example of a height difference between the lift pins 320 in the lift pin assembly 300 of FIG. 3. As illustrated in FIG. 7, a height difference between the lift pins 320 may exist. The height difference between the lift pins 320 may occur in a process of assembling the lift pin assembly 300 or coupling the lift pin assembly 300 to the process chamber 26, or may occur due to unexpected deformation of the lift pin assembly 300. According to an embodiment of the inventive concept, whether a height difference between the lift pins 320 occurs may be determined, and which of the lift pins 320 is higher or lower may be detected.

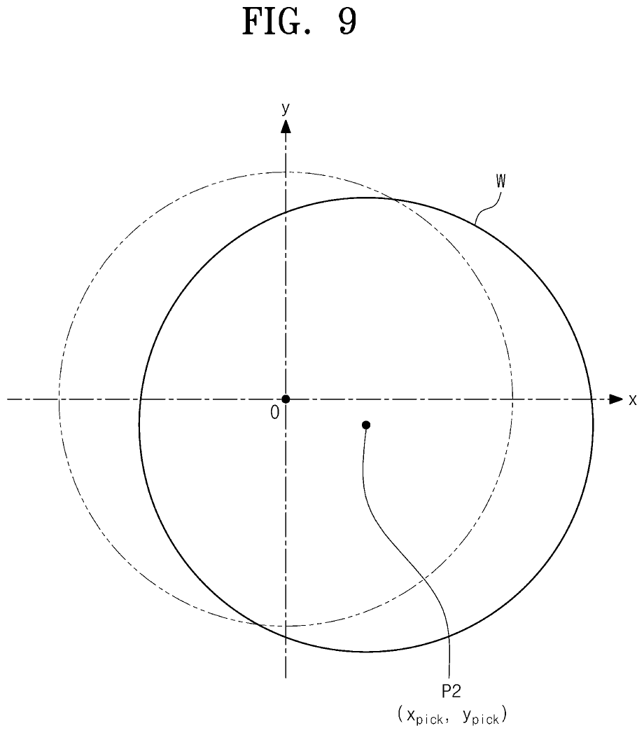

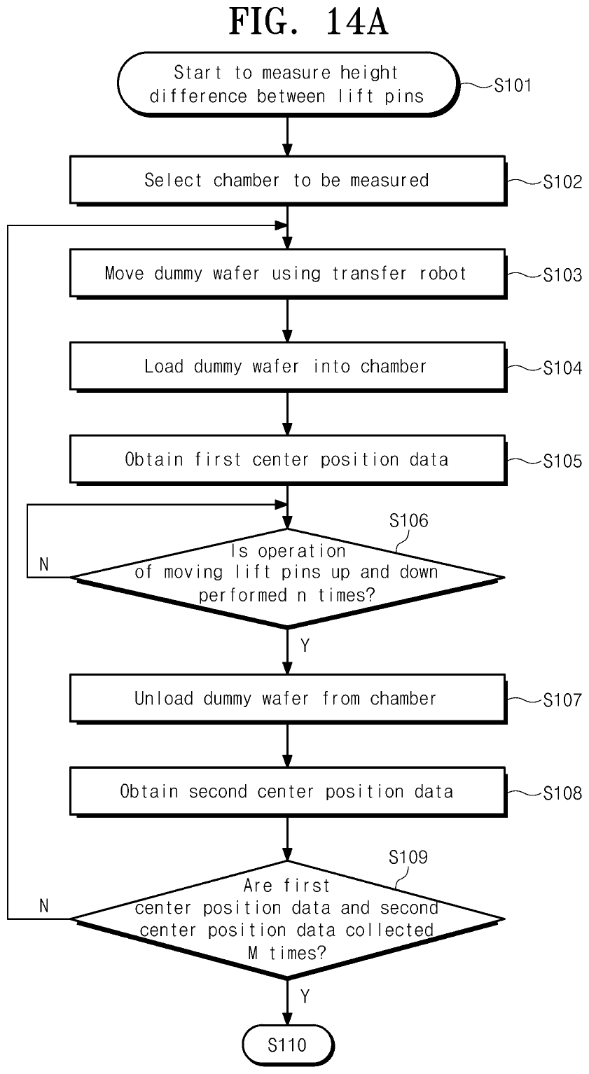

A method for measuring a height difference between lift pins according to an embodiment of the inventive concept will be described below with reference to FIGS. 8 and 13. FIG. 8 illustrates a first center position P1 of a wafer W and the coordinate (x_{place}, y_{place}) of the first center position P1 that are obtained by the processor 600 through an AWC function before the wafer W is loaded onto the support unit 220 of the process chamber 26. FIG. 9 illustrates a second center position P2 of the wafer W and the coordinate (x_{pick}, y_{pick}) of the second center position P2 that are obtained by the processor 600 through the AWC function after the wafer W is unloaded from the support unit 220 of the process chamber 26 and is picked up by the transfer robot 21a. The first center position P1 and the second center position P2 are coordinates with respect to a reference position O. The reference position O may be a virtual position for calculation of the coordinates and may be a position that is located at the center of the seating part of the support unit 220. Meanwhile, it should be noted that the x-y coordinate axes referred to in FIGS. 8 and 9 may differ from the coordinate axes referred to in FIGS. 1 and 2 and are new coordinate axes for the purpose of description.

Various reasons for the difference between the first center position P1 and the second center position P2 may exist. For example, the difference may occur when the wafer W slides downward due to a difference in height between the lift pins 320. In other words, when there is a height difference between at least one of the three lift pins 320 and the other lift pins, the wafer W slides in an inclined direction when the lift pins 320 are moved up and down. The amount of sliding movement of the wafer W is increased as the height difference is increased. In some embodiments, when the height difference between the at least one of the three lift pins 320 and the other lift pins is greater than a predetermined value, the wafer W may slide away from the at least one of the three lift pins 320. To avoid such sliding of the wafer W, the at least one lift pin may be lowered, or the other lift pins are raised to compensate the height difference.

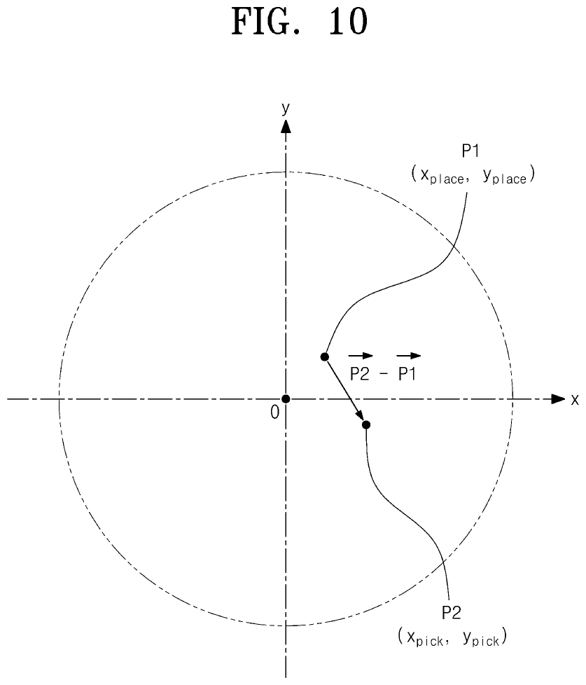

FIG. 10 illustrates a vector difference between the coordinate (x_{pick}, y_{pick}) of the second center position P2 illustrated in FIG. 9 and the coordinate (x_{place}, y_{place}) of the first center position P1 illustrated in FIG. 8. The arrow illustrated in FIG. 10 is a vector of [the coordinate (x_{pick}, y_{pick}) of the second center position P2] minus [the coordinate (x_{place}, y_{place}) of the first center position P1] and is expresses as \vec{P2}−\vec{P1}.

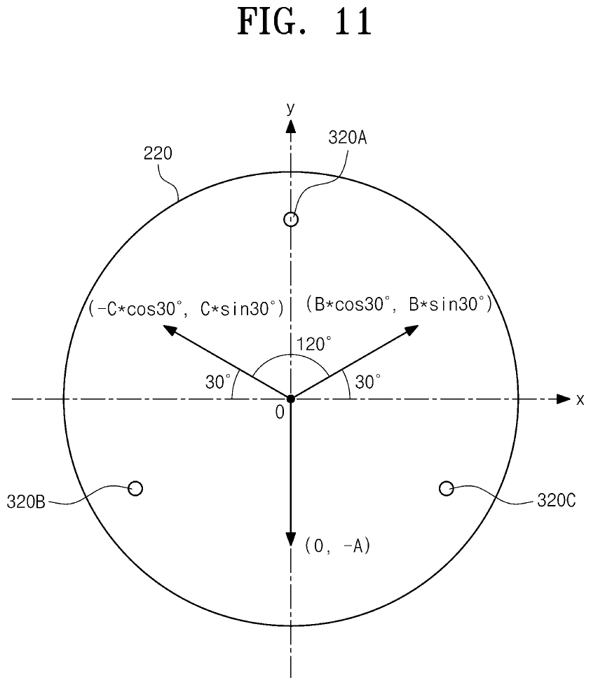

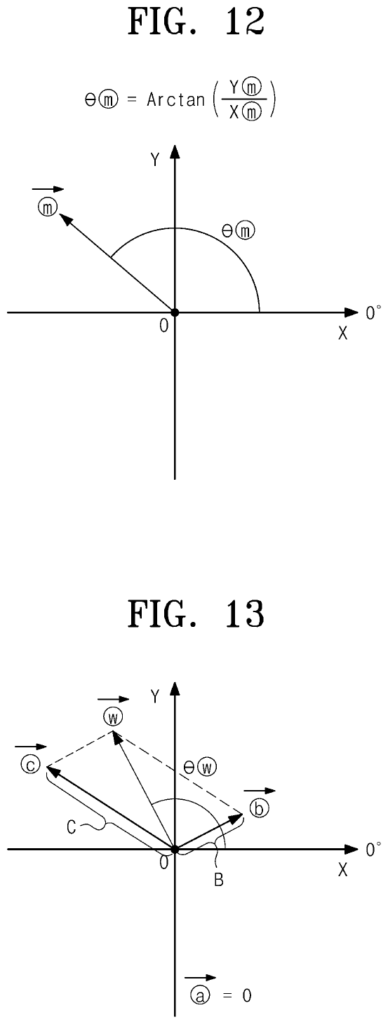

FIGS. 11, 12, and 13 are views illustrating a method for calculating a height difference between lift pins according to an embodiment of the inventive concept. For reference, a moving vector \vec{\textcircled{m}} and a final moving vector \vec{\textcircled{w}} of a wafer W illustrated in FIGS. 12 and 13 are examples for a better understanding of the inventive concept and are expressed as being different from the moving vector \vec{P2}−\vec{P1} of the wafer W illustrated in FIGS. 8 to 10 in terms of magnitude and direction.

The following description will be given with reference to FIG. 11. For example, when one lift pin is in a higher position than the other two lift pins, the wafer W slides in a direction opposite to a direction in which the one lift pin in the higher position is located.

In the support unit 220 according to an embodiment, the lift pins 320 are circumferentially spaced apart from each other at an equal angle of 120 degrees as illustrated in FIG. 11. The lift pins 320 may be displayed in the x-y coordinate system. A force by which the wafer W is slid acts in a direction opposite to a direction in which a lift pin in a relatively high position is located, and wafer-moving forces corresponding to the respective lift pins 320 are expressed as vectors as illustrated in FIG. 11. More specifically, a wafer-sliding force generated by the first lift pin 320A may be expressed as (0, −A). A wafer-sliding force generated by the second lift pin 320B may be expressed as (B*cos 30°, B*sin 30°) and may also be expressed as

$$( \frac{\sqrt{3}}{2} B , \frac{1}{2} B ) .$$

A wafer-sliding force generated by the third lift pin 320C may be expressed as (−C*cos 30°, C*sin 30°) and may also be expressed as

$$( - \frac{\sqrt{3}}{2} C , \frac{1}{2} C ) .$$

The respective vectors have magnitudes A, B, and C depending on the heights of the lift pins 320 and face a 270° direction, a 30° direction, and a 150° direction that are opposite to the directions in which the lift pins 320 are disposed. The positions of the lift pins 320 and the directions of the wafer-sliding forces are listed in Table 1 below.

TABLE 1

| | Lift Pin | Direction |
|---|---|---|
| | Placement | of Wafer-Sliding |
| Lift Pin | Direction | Force |
| First Lift Pin 320A | 90° C. | 270° C. |
| Second Lift Pin 320B | 210° C. | 30° C. |
| Third Lift Pin 320C | 330° C. | 150° C. |

If the wafer W slides when the lift pins 320 are moved up and down, the coordinates of the first center position P1 and the coordinates of the second center position P2 differ from each other as described above with reference to FIGS. 8 to 10. The movement of the wafer W may be expressed as a vector as illustrated in FIG. 10. \vec{P2}−\vec{P1} may be briefly denoted by \vec{\textcircled{m}}, and \vec{\textcircled{n}} may be derived by Equation 1 below.

[Equation 1]

\vec{\textcircled{m}}=(X_{\textcircled{m}},Y_{\textcircled{m}})=(X_{pick}−X_{place},Y_{pick}−Y_{place})

Additionally, referring to FIG. 12, the angle θ_{\textcircled{m}} of the moving vector \vec{\textcircled{m}} of the wafer W may be derived by Equation 2 below.

$${θ}_{} = Arctan ( \frac{{Y}_{}}{{X}_{}} ) \qquad [ Equation 2 ]$$

In an embodiment, a process of measuring the first center position P1 and the second center position P2 is performed M times. In the M measurement processes, when the ratio of the number of effective data to the total number of measurement data is lower than or equal to a set ratio (e.g., less than 80%), the measurement state may be determined to be abnormal, and a measurement error may be determined. In an embodiment, the effective data may be extracted as data in which the difference between the maximum value θ_{\textcircled{m} max} and the minimum value θ_{\textcircled{m} min} of the angle θ_{\textcircled{m}} of the moving vector \vec{\textcircled{m}} of the wafer W, which is derived by Equation 2 above, is smaller than or equal to a set angle (e.g., 7.2° when an error of 2% is applied).

The average of the derived effective data may be derived as the final moving vector \vec{\textcircled{w}} of the wafer W and may be derived by Equation 3 below.

$$= ( \frac{{\sum }_{i = 0}^{K} X {i}_{} }{K} , \frac{{\sum }_{i = 0}^{K} Y {i}_{}}{K} ) , \qquad [ Equation 3 ]$$

(K being the number of effective data)

Referring to FIG. 13, the derived vector \vec{\textcircled{w}} may be a vector sum of \vec{\textcircled{a}} representing the wafer-sliding force (0, −A) generated by the first lift pin 320A, \vec{\textcircled{b}} representing the wafer-sliding force (B*cos 30°, B*sin 30°) generated by the second lift pin 320B, and \vec{\textcircled{c}} representing the wafer-sliding force (−C*cos 30°, C*sin 30°) generated by the third lift pin 320C. The vector \vec{\textcircled{w}} may be expressed as Equation 4 below.

$$= + + = ( {X}_{w ◯} , {Y}_{w ◯} ) = ( \frac{\sqrt{3}}{2} B - \frac{\sqrt{3}}{2} C , - A + \frac{1}{2} B + \frac{1}{2} C ) \qquad [ Equation 4 ]$$

When a height difference between the lift pins 320 is set based on a lift pin located in the lowest position, the lift pin in the lowest position does not affect sliding of the wafer W. That is, the magnitude of a vector caused by the lift pin in the lowest position is equal to 0.

Because the magnitude of the vector caused by the lift pin in the lowest position is equal to 0, [symbol] may be one vector or the sum of two adjacent vectors depending on a moving angle of the wafer W and may be calculated as shown in Table 2.

TABLE 2

| | (X\textcircled{w}, Y\textcircled{w}) | Range of θ\textcircled{w} | | A | B | C |
|---|---|---|---|---|---|---|
| [symbol] | $( \frac{\sqrt{3}}{2} B , \frac{1}{2} B )$ | if θ\textcircled{w} = 30° | → | 0 | $\sqrt{{{X}^{2}}_{} + {{Y}^{2}}_{}}$ | 0 |
| | $\begin{matrix}( \frac{\sqrt{3}}{2} B - \frac{\sqrt{3}}{2} C , \\ \frac{1}{2} B + \frac{1}{2} C )\end{matrix}$ | if 30° < θ\textcircled{w}< 150° | → | 0 | $\vert \frac{1}{\sqrt{3}} {X}_{} + {Y}_{} \vert$ | $\vert - \frac{1}{\sqrt{3}} {X}_{} + {Y}_{} \vert$ |
| | $( - \frac{\sqrt{3}}{2} C , \frac{1}{2} C )$ | if θ\textcircled{w} = 150° | → | 0 | 0 | $\sqrt{{{X}^{2}}_{} + {{Y}^{2}}_{}}$ |
| | $( - \frac{\sqrt{3}}{2} C , - A + \frac{1}{2} C )$ | if 150° < θ\textcircled{w} < 270° | → | $\vert - \frac{1}{\sqrt{3}} {X}_{} - {Y}_{} \vert$ | 0 | $\vert - \frac{2}{\sqrt{3}} {X}_{} \vert$ |
| | (0, −A) | if θ\textcircled{w} = 270° | → | [−Y\textcircled{w}] | 0 | 0 |
| | $( \frac{\sqrt{3}}{2} B , - A + \frac{1}{2} B )$ | if 300° < θ\textcircled{w} or θ\textcircled{w} < 30° | → | $\vert \frac{1}{\sqrt{3}} {X}_{} - {Y}_{} \vert$ | $\vert \frac{2}{\sqrt{3}} {X}_{} \vert$ | 0 |

Measurement of a height difference between the lift pins depending on a movement of the wafer W, which is inferred from Table 2 above, may be summarized as in Table 3 below.

TABLE 3

| Case | Measurement | |
|---|---|---|
| No. | Value | Conclusion |
| 1 | When three vectors | Three lift pins are all |
| | are equal to 0 | located at the same |
| | | height. |
| 2 | When two vectors | Two lift pins are located |
| | are equal to 0 | at the same height |
| | | and one lift pin is located |
| | | in a higher position. |
| 3 | When one vector | Two lift pins are located |
| | is equal to 0 | in a higher position |
| | | than one lift pin in the |
| | | lowest position. |

Referring again to FIG. 7, the state of FIG. 7 corresponds to Case 3 in Table 3 above, and Δh₁:Δh₂ may be expressed as Equation 5 below.

$$Δ {h}_{1} \text{:} Δ {h}_{2} = \frac{( smaller one of two non \text{-} zero vector values )}{( larger one of two non \text{-} zero vector values )} \qquad [ Equation 5 ]$$

Equation 5 above may be expressed as Equation 6 and Equation 7 and may obtain a height difference between the lift pins 320. In Equation 6 and Equation 7 below, Δh1 means a small height difference between two lift pins, and Δh2 means a large height difference between two lift pins.

$$\begin{matrix}Δ {h}_{1} = \frac{( smaller one of two non \text{-} zero vector values )}{( larger one of two non \text{-} zero vector values )} * Δ {h}_{2} & [ Equation 6 ] \\ Δ {h}_{2} = \frac{( larger one of two non \text{-} zero vector values )}{( smaller one of two non \text{-} zero vector values )} * Δ {h}_{1} & [ Equation 7 ]\end{matrix}$$

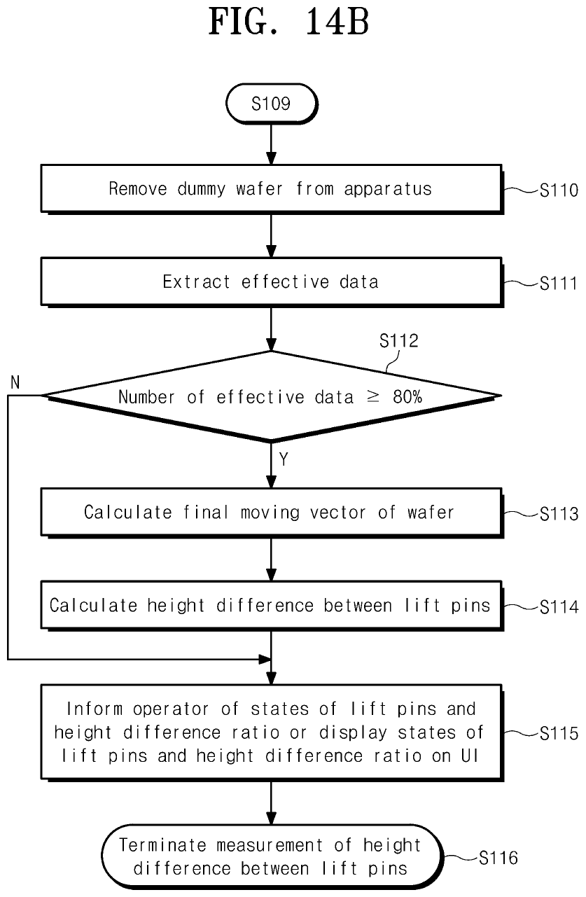

FIGS. 14A and 14B illustrate a flowchart showing an operation algorithm of an apparatus for measurement of a height difference between lift pins according to an embodiment of the inventive concept. A height difference measurement algorithm according to an embodiment of the inventive concept will be described below with reference to FIG. 14. Referring to FIG. 14, a wafer W according to an embodiment may be a dummy wafer. The height difference measurement algorithm according to the inventive concept may be operated by an operating command of an operator when the operator wants to perform a height difference measurement function. For example, when the operator inputs a measurement command of the height difference measurement function, measurement of a height difference between the lift pins 320 starts (S101). The operator selects a process chamber 26 to be measured, among the plurality of process chambers 26 (S102). The dummy wafer is moved by the transfer robot 21a (S103). The dummy wafer is loaded into the selected process chamber 26 by the transfer robot 21a (S104). In the process in which the dummy wafer is loaded into the process chamber 26 by the transfer robot 21a, the position measurement sensor 205 obtains data on a first center position that is the position of the center of the dummy wafer (S105). After the dummy wafer is loaded into the process chamber 26, an operation of moving the lift pins 320 up and down is performed N times (S106). Operations of the lift pins 320 may be controlled by a controller (not illustrated). Whether a movement of the dummy wafer is caused by a height difference between the lift pins 320 or another factor may be determined, by performing the vertical movement of the lift pins 320 N times. Furthermore, by performing the vertical movement of the lift pins 320 N times, a movement of the center position of the dummy wafer may converge to effective data. In an embodiment, N may be selected to be an appropriate value by which the movement of the center position of the dummy wafer converges to effective data.

After the vertical movement of the lift pins 320 is performed N times, the transfer robot 21a unloads the dummy wafer from the process chamber 26 (S107). In the process in which the dummy wafer is unloaded from the process chamber 26 by the transfer robot 21a, the position measurement sensor 205 obtains data on a second center position that is the position of the center of the dummy wafer (S108).

The first center position data and the second center position data are collected M times by sequentially performing steps S103 to S108 M times (S109). Thereafter, the dummy wafer is removed from the apparatus (S110).

The processor 600 extracts effective data from the first center position data and the second center position data collected M times (S111). In an embodiment, the effective data may be extracted as data in which the difference between the maximum value θ_{\textcircled{m} max} max and the minimum value θ_{\textcircled{m} min} of the angle θ_{\textcircled{m}} of the moving vector \vec{\textcircled{m}} of the wafer W, which is derived by Equation 2 above, is smaller than or equal to the set angle (e.g., 7.2° when an error of 2% is applied). When the ratio of the number of derived effective data to the total number of measurement data is higher than or equal to the set ratio (e.g., more than 80%), the processor 600 may determine a normal measurement state and may proceed to a next step (S112). In contrast, when the ratio of the number of effective data to the total number of measurement data is lower than or equal to the set ratio (e.g., less than 80%), the processor 600 may determine an abnormal measurement state and a measurement error and may immediately inform the operator of the determination.

The processor 600 derives a final moving vector \vec{\textcircled{w}} of the wafer W through Equation 3 by using the effective data (S113). The processor 600 calculates a height difference between the lift pins 320 through steps that use Equations 4 to 7 and Table 2 and 3, by using the final moving vector \vec{\textcircled{w}} of the wafer W (S114).

A controller (not illustrated) that controls the wafer treating equipment 1 may inform the operator of the states of the lift pins 320 and the difference ratio as the derived height difference between the lift pins 320 by using an alarm, or may display the states of the lift pins 320 and the difference ratio as a UI on an operator-visible display (S115). When the height difference between the lift pins 320 is large enough to require maintenance, the controller may inform the operator of a necessity for maintenance as an alarm. The alarm may be displayed as a warning on a screen of the display, or may be provided as a sound.

When steps S102 to S115 are completed, the measurement of the height difference between the lift pins 320 is terminated (S116).

In the above-described embodiments, it has been described that the process chamber 26 has a structure for performing an etching process. However, the process chamber 26 may be applied to various types of processes having a structure for loading a wafer onto the support unit 220 using lift pins. For example, the process chamber 26 may be configured to perform a process such as a deposition process, an etching process, a measurement process, a bake process, a cleaning process, a drying process, an exposing process, a coating process, or a developing process.

In the above-described embodiments, it has been described that the three lift pins are provided. However, even though four, five, or more lift pins are provided, a height difference between the lift pins may be measured by varying the above equations through the concept of the inventive concept.

In an embodiment of the inventive concept, a non-transitory computer readable medium having a program stored therein for sequentially performing the substrate treating method according to the embodiment may be provided.

The non-transitory computer readable medium refers to a medium that semi-permanently stores data and is readable by a computer, rather than a medium (e.g., a resister, a cache, or a memory) that stores data for a short period of time. Specifically, the above-described various applications or programs may be stored in a non-transitory computer readable medium such as a CD, a DVD, a hard disc, a blue-ray disc, a USB, a memory card, and a ROM.

According to the various embodiments of the inventive concept, after assembly of a process chamber (PM), occurrence or non-occurrence of a height difference between lift pins may be identified without disassembly of the process chamber.

According to the various embodiments of the inventive concept, occurrence or non-occurrence of a height difference between lift pins may be identified in a simple manner by using center position coordinate information of a wafer (e.g., data collected through an auto wafer centering (AWC) function).

According to the various embodiments of the inventive concept, a lift pin having problems in assembly and height setting among lift pins may be identified.

According to the various embodiments of the inventive concept, assembly of lift pins may be evaluated in a simple manner.

According to the various embodiments of the inventive concept, occurrence or non-occurrence of human and environmental errors that are likely to occur between assembly of lift pins and assembly of a process chamber may be identified after the assembly of the process chamber.

According to the various embodiments of the inventive concept, occurrence or non-occurrence of a height difference between lift pins may be identified even during operation of an apparatus, and a chamber release frequency may be reduced by determining a failure in the lift pins.

Effects of the inventive concept are not limited to the above-described effects, and any other effects not mentioned herein may be clearly understood from this specification and the accompanying drawings by those skilled in the art to which the inventive concept pertains.

The above description exemplifies the inventive concept. Furthermore, the above-mentioned contents describe exemplary embodiments of the inventive concept, and the inventive concept may be used in various other combinations, changes, and environments. That is, variations or modifications can be made to the inventive concept without departing from the scope of the inventive concept that is disclosed in the specification, the equivalent scope to the written disclosures, and/or the technical or knowledge range of those skilled in the art. The written embodiments describe the best state for implementing the technical spirit of the inventive concept, and various changes required in specific applications and purposes of the inventive concept can be made. Accordingly, the detailed description of the inventive concept is not intended to restrict the inventive concept in the disclosed embodiment state. In addition, it should be construed that the attached claims include other embodiments.

While the inventive concept has been described with reference to embodiments, it will be apparent to those skilled in the art that various changes and modifications may be made without departing from the spirit and scope of the inventive concept. Therefore, it should be understood that the above embodiments are not limiting, but illustrative.

1. An apparatus for treating a substrate, the apparatus comprising:
a chamber configured to provide a treatment space in which the substrate is treated;
a support unit provided in the treatment space and configured to support the substrate, the support unit including a plurality of lift pins configured to move upward or downward to locate the substrate;
a transfer robot configured to load the substrate into the treatment space or unload the substrate from the treatment space;
a position measurement sensor configured to measure a first center position being a position of the center of the substrate with respect to a reference position that is measured before the transfer robot loads the substrate onto the support unit and a second center position being a position of the center of the substrate with respect to the reference position that is measured after the transfer robot picks up the substrate unloaded from the support unit; and
a processor configured to derive a difference in height between at least one of the plurality of lift pins and the other lift pins from a vector difference between the first center position and the second center position.

2. The apparatus of claim 1,
wherein the position measurement sensor is an auto wafer centering (AWC) sensor installed on the top or bottom of an opening of the chamber and is configured to measure a position of the substrate passing through the opening of the chamber.

3. The apparatus of claim 1,
wherein each of the first center position and the second center position includes an x-coordinate and a y-coordinate.

4. The apparatus of claim 1,
wherein the plurality of lift pins are coupled to a support plate, and
wherein the support plate is connected to an actuator configured to provide a driving force to raise and lower the support plate in an up/down direction.

5. The apparatus of claim 1,
wherein the processor of the apparatus is configured to:
cause to perform an operation of loading the substrate onto the support unit and unloading the substrate from the support unit a plurality of times;
cause to measure the first center position a plurality of times in response to loading the substrate onto the support unit the plurality of times and measures the second center position a plurality of times in response to unloading the substrate from the support unit the plurality of times; and
derive the difference in height between the at least one of the plurality of lift pins and the other lift pins from a vector difference between an average value of a plurality of first center positions measured the plurality of times and an average value of a plurality of second center positions measured the plurality of times.

6. The apparatus of claim 1,
wherein at a time before the second center position is measured and after the first center position is measured, the plurality of lift pins are raised and lowered a plurality of times, with the substrate loaded onto the support unit.

7. The apparatus of claim 1,
wherein the plurality of lift pins include three lift pins circumferentially spaced apart from each other at an angle of 120 degrees with respect to the center of the support unit.

8. The apparatus of claim 1,
wherein in response to the derived difference in height, the processor is further configured to cause at least one of the plurality of lift pins to move up or move down to compensate the difference in height.

9. The apparatus of claim 1, further comprising:
an alarm configured to generate a sound during a time when the difference in height between the at least one of the plurality of lift pins and the other lift pins is derived.

10.-19. (canceled)

20. A non-transitory computer readable medium for storing a program code, wherein the program code, which executed by a processor, cause the processor to:
obtain a first center position being a position of the center of a substrate with respect to a reference position that is measured before a transfer robot loads the substrate onto a support unit provided in a process chamber, the support unit including a plurality of lift pins;
obtain a second center position being a position of the center of the substrate with respect to the reference position that is measured after the transfer robot picks up the substrate unloaded from the support unit; and
derive a difference in height between at least one of the plurality of lift pins and the other lift pins from a vector difference between the first center position and the second center position.
